(19) United States
(12) Patent Application Publication
(10) Pub. No.: US 2010/0141307 A1
(43) Pub. Date: Jun. 10, 2010

(54) Frequency multiplier and method for frequency multiplying

(76) Inventors: Ta-Yung Yang, Milpitas, CA (US); Pei-Sheng Tsu, Shulin City (TW); Chih-Ho Lin, Hsinchu City (TW); Chuan-Chang Li, Sinfong Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/591,375

(22) Filed: Nov. 18, 2009

Related U.S. Application Data
(60) Provisional application No. 61/201,183, filed on Dec. 8, 2008.

(51) Int. Cl. H03B 19/00

(52) U.S. Cl. 327/119

(57) ABSTRACT

A frequency multiplier according to the present invention comprises a period-to-voltage converter that generates a control signal in response to the period of an input signal. An oscillator generates an output signal in accordance with the control signal. The level of the control signal is corrected to the frequency of the input signal. The control signal is coupled to determine the frequency of the output signal.

### BACKGROUND OF THE INVENTION

1. Filed of Invention

The present invention relates to a frequency converter, and more particularly, to the frequency multiplier and method for frequency multiplying.

2. Description of Related Art

A frequency multiplier is commonly used to multiply the base frequency for generating a high frequency clock signal, it can be used to many electronic devices, such as the BLDC motor controllers and the synchronized switching of DC/DC buck/boost converters, etc. The conventional frequency multiplier is complex.

### SUMMARY OF THE INVENTION

An object of the present invention is to provide a simple and low cost circuit for the frequency multiplier and a method used therein.

A frequency multiplier according to a preferred embodiment of the present invention includes a period-to-voltage converter generating a control signal in response to the period of an input signal. An oscillator generates an output signal in accordance with the control signal. The level of the control signal is corrected to the frequency of the input signal. The control signal determines the frequency of the output signal.

According to another preferred embodiment of the present invention, the frequency multiplier further includes a level-shift circuit. The level-shift circuit generates a differential signal in according with the control signal. The differential signal is coupled to the oscillator for generating the output signal.

A method for frequency multiplying according to a preferred embodiment of the present invention includes generating a control signal in response to the period of the input signal, and generating the output signal in accordance with the control signal. The level of the control signal is corrected to the frequency of the input signal. The control signal is coupled to determine the frequency of the output signal. The method for frequency multiplying further includes generating a differential signal in according with the control signal. The differential signal is utilized to generate the output signal.

### BRIEF DESCRIPTION OF ACCOMPANIED DRAWINGS

The accompanying drawings are included to provide a further understanding of the present invention, and are incorporated in and constitute a part of this specification. The drawings illustrate embodiments of the present invention and, together with the description, serve to explain the principles of the present invention. In the drawings,

FIG. 1 shows a schematic diagram of a frequency multiplier;

FIG. 2 shows a block diagram of a preferred embodiment of the frequency multiplier according to the present invention;

FIG. 3 shows the circuit schematic of a preferred embodiment of a period-to-voltage converter of the frequency multiplier according to the present invention;

FIG. 4 shows the circuit schematic of the pulse generators of the period-to-voltage converter according to the present invention;

FIG. 5 shows waveform of the period-to-voltage converter of the frequency multiplier according to the present invention;

FIG. 6 shows the circuit schematic of a preferred embodiment of a level-shift circuit of the frequency multiplier according to the present invention; and

FIG. 7 shows the circuit schematic of a preferred embodiment of an oscillator of the frequency multiplier according to the present invention.

### DETAILED DESCRIPTION OF PREFERRED EMBODIMENTS

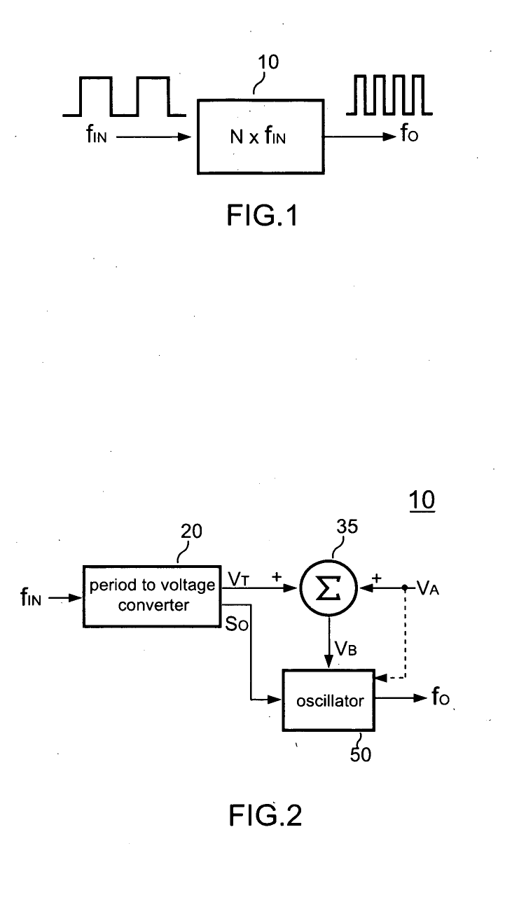

FIG. 1 shows the circuit schematic of a frequency multiplier according to the present invention. An input signal f_{IN} is coupled to the input of the frequency multiplier 10. The frequency multiplier 10 (generates an output signal f_{O} with a frequency of the input signal f_{IN} multiplied by N.

FIG. 2 shows the block diagram of a preferred embodiment of the frequency multiplier 10 of the present invention. The frequency multiplier 10 comprises a period-to-voltage converter 20 and an oscillator 50. The period-to-voltage converter 20 generates a control signal V_{T} in response to the period of the input signal f_{IN}. The level of the control signal V_{T} is corrected to the frequency of the input signal f_{IN}. It means that the level of the control signal V_{T} is also corrected to the period of the input signal f_{IN}. The oscillator 50 generates the output signal f_{O} in accordance with the control signal V_{T}. The control signal V_{T} is coupled to the oscillator 50 and operate as a trip-point voltage of the oscillator 50. The trip-point voltage determines the frequency of the output signal f_{O}. The bias signal V_{A} is coupled to the oscillator 50 for generating the output signal f_{O}. The period-to-voltage converter 20 further generates a pulse signal So coupled to the oscillator 50.

Another preferred embodiment of the present invention, the frequency multiplier 10 further includes a level-shift circuit 35. The level-shift circuit 35 is coupled between the period-to-voltage converter 20 and the oscillator 50 for generating a differential signal V_{B} in according with the control signal V_{T} and a bias signal V_{A}. The differential signal V_{B} is coupled to the oscillator 50 for generating the output signal f_{O}.

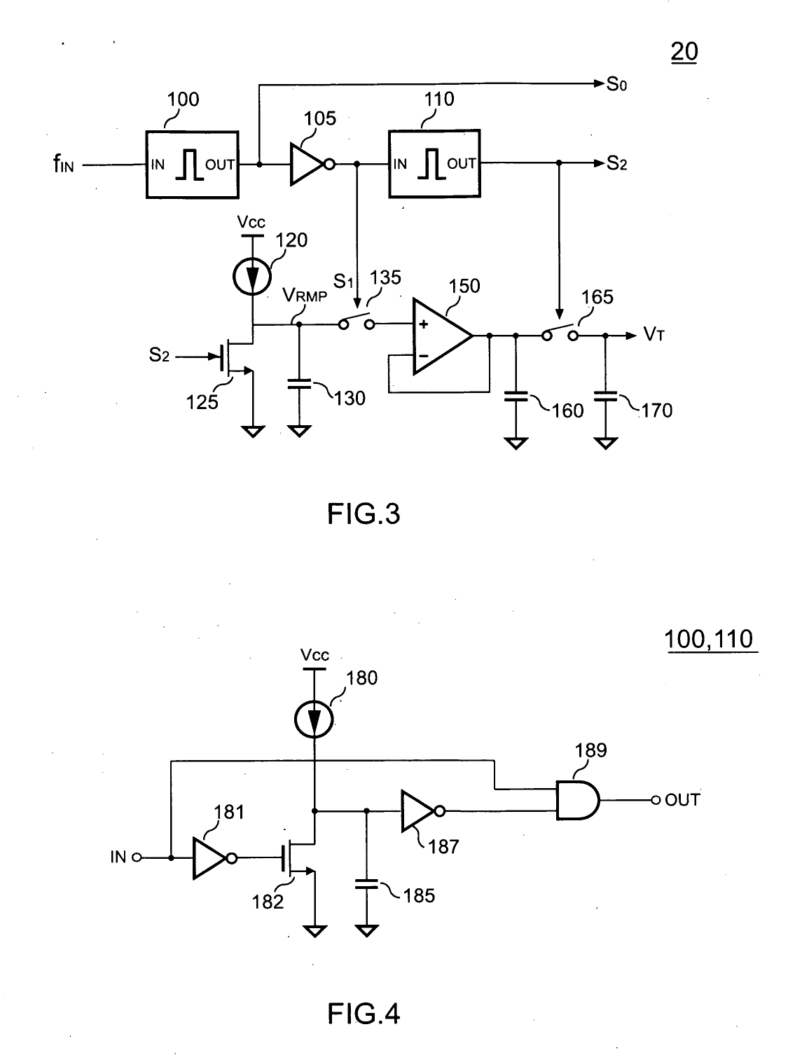

FIG. 3 shows the circuit schematic of a preferred embodiment of the period-to-voltage converter 20 of the frequency multiplier 10 according to the present invention. The input signal f_{IN} is utilized to generate the pulse signal S₀ through a pulse generator 100. The pulse signal S₀ is coupled to an inverter 105 to generate a pulse signal S₁. The pulse signal S₁ is further coupled to a pulse generator 110 to generate a pulse signal S₂. Therefore, the pulse signals S₀, S₁ and S₂ are corrected to the period of the input signal f_{IN}.

A current source 120 is connected between a supply voltage V_{CC} and a transistor 125. The transistor 125 is connected between the current source 120 and a ground. A first terminal of a capacitor 130 is connected to the current source 120 and the transistor 125. A second terminal of the capacitor 130 is connected to the ground. The transistor 125 is controlled by the pulse signal S₂. The capacitor 130 is charged by the current source 120 when the pulse signal S₂ is disabled and the voltage of the capacitor 130 will gradually increase. The capacitor 130 is discharged when the pulse signal S₂ is enabled and the transistor 125 is turned on.

Therefore, a ramp signal V_{RMP} across the capacitor 130 will begin to rise with a slope that is determined by the amplitude of the current of the current source 120 and the capacitance of the capacitor 130 when the pulse signal S₂ is disabled. In other word, the current source 120 and the capacitor 130 are utilized to generate the ramp signal V_{RMP} in response to the pulse signal S₂. It means that the current source 120 and the capacitor 130 are utilized to generate the ramp signal V_{RMP} in response to the input signal f_{IN} due to the pulse signal S₂ is generated by the pulse generators 100, 110 and the inverter 105 in response to the input signal f_{IN}.

Switches 135, 165, a buffer amplifier 150 and capacitors 160, 170 develop a sample-and-hold circuit. The switch 135 is connected between the capacitor 130 and a positive input of the buffer amplifier 150. The switch 165 is connected between the capacitor 160 and the capacitor 170. A positive input of the buffer amplifier 150 is connected to the output of the capacitor 130 for receiving the ramp signal V_{RMP} through the switch 135. A negative input of the buffer amplifier 150 is connected to an output of the buffer amplifier 150. The output of the buffer amplifier 150 is further connected to the capacitor 160. The capacitor 160 is connected to the capacitor 170 through the switch 165. The capacitors 160 and 170 are utilized to generate the control signal V_{T} in response to the ramp signal V_{RMP}. The capacitor 160 is used to hold the ramp signal V_{RMP} at the capacitor 130 through the switch 135 when the pulse signal S₁ is enabled.

The capacitor 170 is used to hold an output at the capacitor 160 through the switch 165 when the pulse signal S₂ is enabled. The switch 135 is controlled by the pulse signal S₁. The switch 165 is controlled by the pulse signal S₂. Therefore, the sample-and-hold circuit receives the ramp signal V_{RMP} when the pulse signal S₁ is enabled. Therefore, the sample-and-hold circuit samples a predetermine peak value of the ramp signal V_{RMP} to generate the control signal V_{T} when the pulse signal S₂ is enabled. In other word, the sample-and-hold circuit generates the control signal V_{T} by sampling the ramp signal V_{RMP} in response to the input signal f_{IN}, and the level of the control signal V_{T} is corrected to the period of the input signal f_{IN}.

Another embodiment of the period-to-voltage converter 20 according to the present invention, the most of the circuits of the period-to-voltage converter 20 of this embodiment are the same as the first embodiment (as shown in FIG. 3) and no more description here, the main difference compared to the first embodiment is that the sample-and-hold circuit of this embodiment develops by switch 135 and capacitor 160 without the switch 165, the buffer amplifier 150 and the capacitor 170. The capacitor 160 is used to hold the ramp signal V_{RMP} to generate the control signal V_{T} through the switch 135 when the pulse signal S₁ is enabled. The sample-and-hold circuit of the this embodiment generates the control signal V_{T} by sampling the ramp signal V_{RMP} in response to the input signal f_{IN}, and the level of the control signal V_{T} is corrected to the period of the input signal f_{IN}.

FIG. 4 shows the circuit schematic of a preferred embodiment of the pulse generators 100 or 110 of the period-to-voltage converter 20 according to the present invention. A current source 180 is connected between the supply voltage V_{CC} and a transistor 182. The transistor 182 is connected between the current source 180 and the ground. A first terminal of a capacitor 185 is connected to the current source 180 and the transistor 182. A second terminal of the capacitor 185 is connected to the ground. The transistor 182 is controlled by an input signal IN (the input signal f_{IN} or the pulse signal S₁) through an inverter 181. The capacitor 185 is charged by the current source 180 when the input signal IN is enabled and the voltage of the capacitor 185 will gradually increase. The capacitor 185 is discharged by the ground when the input signal IN is disabled and the transistor 182 is turned on. Therefore, the current source 180 is coupled to charge a capacitor 185. The input signal IN is coupled to discharge the capacitor 185 via the inverter 181 and the transistor 182.

The input signal IN is further coupled to the input of an AND gate 189. Another, input of the AND gate 189 is coupled to the capacitor 185 through an inverter 187 for generating an output signal OUT (the pulse signal S₀, the pulse signal S₁ or the pulse signal S₂). Therefore, the output of the pulse generator will generate a pulse output signal OUT in response to the rising edge of the input signal IN.

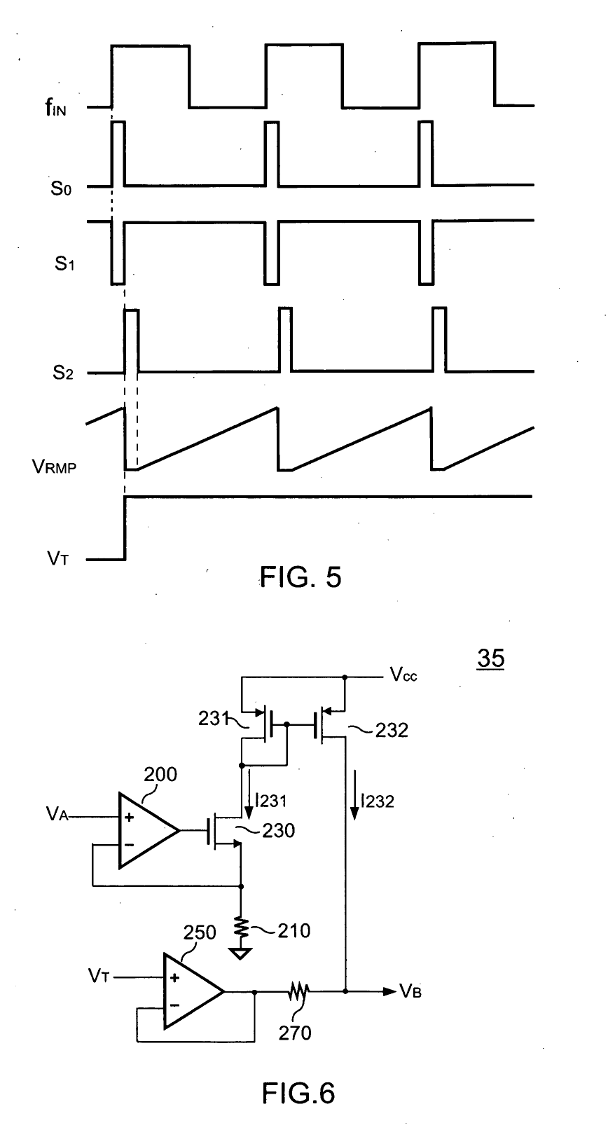

FIG. 5 shows waveforms of the input signal f_{IN}, the ramp signal V_{RMP}, the pulse signals S₀, S₁, S₂ and the control signal V_{T} (as show in the FIG. 3). Referring to the FIG. 3, because of the output of the pulse generator will generate the pulse output signal OUT in response to the rising edge of the input signal IN. Therefore, the output of the pulse generator 100 of the period-to-voltage converter 20 will generate the pulse signal S₀ in response to the rising edge of the input signal f_{IN}. Addition, the output of the inverter 105 of the period-to-voltage converter 20 will inverter the pulse signal S₀ to generate the pulse signal S₁ in response to the rising edge of the pulse signal S₀. The output of the pulse generator 110 will generate the pulse signal S₂ in response to the rising edge of the pulse signal S₁. Further, the ramp signal V_{RMP} across the capacitor 130 will begin to rise with a slope in response to the falling edge of the pulse signal S₂. The sample-and-hold circuit generates the control signal V_{T} in response to the rising edges of the pulse signals S₁ and S₂.

According to above, the period-to-voltage converter 20 generates the pulse signals S₀, S₁ and S₂ in response to the input signal f_{IN} (as shown in FIG. 3). Further, the period-to-voltage converter 20 generates the control signal V_{T} in response to the pulse signals S₁ and S₂. Therefore, the control signal V_{T} is correlated to the input signal f_{IN}.

FIG. 6 shows the circuit schematic of a preferred embodiment of the level-shift circuit 35 of the frequency multiplier 10 according to the present invention. The control signal V_{T} is supplied to a positive input of a buffer amplifier 250. A negative input of the buffer amplifier 250 is connected to an output of the buffer amplifier 250. The output of the buffer amplifier 250 generates the differential signal V_{B} via a resistor 270. An operational amplifier 200, a resistor 210 and transistors 230, 231, 232 develop a voltage-to-current converter generating an output current I₂₃₂ in response to the bias signal V_{A}.

The bias signal V_{A} is supplied to a positive input of the operational amplifier 200. The resistor 210 is connected between a negative input of the operational amplifier 200 and the ground. A gate of the transistor 230 is connected to an output of the operational amplifier 200. A source of the transistor 230 is connected to the resistor 210. The voltage-to-current converter converts the bias signal V_{A} into a current signal I₂₃₁ via the resistor 210. The transistor 231 and the transistor 232 develop a current mirror. Two sources of the transistor 231 and the transistor 232 are coupled to the supply voltage V_{CC}. A drain of the transistor 231 is connected to a drain of the transistor 230 and two gates of the transistor 231 and transistor 232. The current signal I₂₃₁ is generated by the drain of the transistor 231. The current mirror receives the current signal I₂₃₁ to generate the output current I₂₃₂. The output current I₂₃₂ is generated by a drain of the transistor 232.

The output current I₂₃₂ is coupled to generate a level-shift voltage at the resistor 270. The differential signal V_{B} can be designed as,

V_{B}=V_{A}+V_{T} (1)

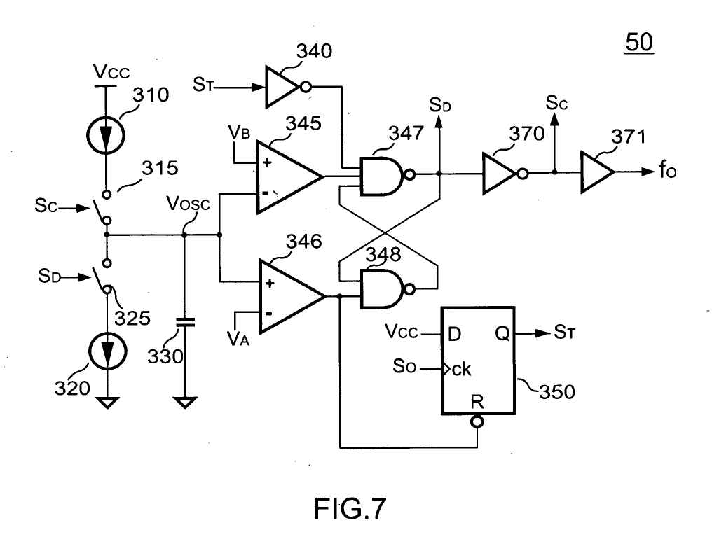

FIG. 7 shows the circuit schematic of a preferred embodiment of the oscillator 50 of the frequency multiplier 10 according to the present invention. As shown, the oscillator 50 includes current sources 310, 320, switches 315, 325, a capacitor 330, comparators 345, 346, NAND gates 347, 348, inverters 340, 370, a flip-flop 350 and a buffer 371. The current sources 310, 320, switches 315, 325 and the capacitor 330 are utilized to generate the oscillation signal V_{OSC} in response to the trip-point voltage.

The switch 315 is connected between the current source 310 and the capacitor 330. The current source 310 is coupled to the supply voltage V_{CC} for charging the capacitor 330. The switch 325 is connected between the capacitor 330 and the current source 320. The current source 320 is coupled to the ground for discharging the capacitor 330. A negative terminal of the capacitor 330 is connected to the ground. An oscillation signal V_{OSC} is generated at a positive terminal of the capacitor 330.

The differential signal V_{B} and the bias signal V_{A} is coupled to the comparators 345 and 346 to operate as the trip-point voltage. The differential signal V_{B} is coupled to a positive input of the comparator 345. The bias signal V_{A} is coupled to a negative input of the comparator 346. A negative input of the comparator 345 and a positive input of the comparator 346 are coupled to the capacitor 330 to receive the oscillation signal V_{OSC}. The differential signal V_{B} is produced by the control signal V_{T} and the bias signal V_{A} (as shown in FIG. 2). The outputs of comparators 345 and 346 are coupled to a latch circuit formed by NAND gates 347 and 348. The output of the comparator 345 is coupled to a first input of the NAND gate 347. The output of the comparator 346 is coupled to a first input of the NAND gate 348. An output of the NAND gate 348 is coupled to a second input of the NAND gate 347. An output of the NAND gate 347 is coupled to a second input of the NAND gate 348.

The output of the latch generate a discharge signal S_{D} coupled to control the switch 325 for discharging the capacitor 330 when the voltage of the oscillation signal V_{OSC} is higher than the trip-point voltage (the differential signal V_{B}). The discharge signal S_{D} is further connected to an inverter 370 for generating a charge signal S_{C} coupled to control the switch 315. The switch 315 is enabled to charge the capacitor 330 once the voltage of the oscillation signal V_{OSC} is lower than the trip-point voltage (the bias signal V_{A}). The charge signal S_{C} is connected to the input of the buffer 371 for generating the output signal f_{O}. Therefore, the output signal f_{O} is correlated to the oscillation signal V_{OSC}.

Furthermore, the pulse signal S₀ is coupled to the clock input ck of the flip-flop 350 to trigger the flip-flop 350. The input D of the flip-flop 350 is coupled to receive the supply voltage V_{CC}. The output Q of the flip-flop 350 generates an output signal S_{T}. The output signal S_{T} of the flip-flop 350 is coupled to enable the discharge signal S_{D} through the inverter 340 and the NAND gate 347. The output of the comparator 346 is coupled to the reset input R of the flip-flop 350 to reset the flip-flop 350. The output signal f_{O} of the frequency multiplier 10 is thus synchronized with the input signal f_{IN} of the frequency multiplier 10.

The current of the current source 310 is correlated to the current of the current source 120 (as shown in FIG. 3). The time constant of the oscillator 50 generating the output signal f_{O} is corrected to the time constant of the period-to-voltage converter 20 generating the control signal V_{T}.

$$\begin{matrix}{V}_{RMP} = \frac{{I}_{120} \times {Tf}_{IN}}{{C}_{130}} & ( 2 ) \\ m \times {Tf}_{O} = \frac{{C}_{330} \times {V}_{RMP}}{{I}_{310}} & ( 3 ) \\ m \times {Tf}_{O} = \frac{{C}_{330}}{{I}_{310}} \times \frac{{I}_{120}}{{C}_{130}} \times {Tf}_{IN} & ( 4 ) \\ \frac{{Tf}_{O}}{{Tf}_{IN}} = 1 / m \times \frac{{C}_{330}}{{C}_{130}} \times \frac{{I}_{120}}{{I}_{310}} & ( 5 )\end{matrix}$$

where I₁₂₀ is the current of the current source 120; I₃₁₀ is the current of the current source 310; C₁₃₀ is the capacitance of the capacitor 130 (as shown in FIG. 3); C₃₃₀ is the capacitance of the capacitor 330; Tf_{IN} is the period of the input signal f_{IN}, Tf_{O} is the period of the output signal f_{O}; m is the maximum duty cycle of the oscillator 50 such as 0.9, it is determined by the ratio of the current source 310 and 320.

The equation (5) shows the time constant of generating the output signal f_{O} and the time constant of generating the control signal V_{T} to determine a multiplier of the frequency multiplying.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims or their equivalents.

What is claimed is:

1. A frequency multiplier, comprising:
a period-to-voltage converter, the period-to-voltage converter generating a control signal in response to the period of an input signal; and
an oscillator, the oscillator generating an output signal in accordance with the control signal;
wherein the level of the control signal is corrected to the frequency of the input signal, the control signal is coupled to operate as a trip-point voltage of the oscillator, the trip-point voltage determines the frequency of the output signal.

2. The frequency multiplier as claimed in claim 1, wherein a time constant of the oscillator is corrected to a time constant of the period-to-voltage converter.

3. The frequency multiplier as claimed in claim 1, wherein the output signal of the frequency multiplier is synchronized with the input signal of the frequency multiplier.

4. The frequency multiplier as claimed in claim 1, further comprising:
a level-shift circuit, the level-shift circuit generating a differential signal in according with the control signal;
wherein the differential signal is coupled to the oscillator for generating the output signal.

5. The frequency multiplier as claimed in claim 4, wherein the level-shift circuit further receives a bias signal for generating the differential signal in according with the control signal and the bias signal.

6. The frequency multiplier as claimed in claim 1, wherein the period-to-voltage converter comprising:
a capacitor, the capacitor generating a ramp signal;
a current source, the current source charging the capacitor for generating the ramp signal in response to the input signal; and
a sample-and-hold circuit, the sample-and-hold circuit generating the control signal by sampling the ramp signal in response to the input signal;
wherein the level of the control signal is corrected to the period of the input signal.

7. The frequency multiplier as claimed in claim 6, wherein the oscillator comprising:
a capacitor, the capacitor of the oscillator generating an oscillation signal; and
a current source, the current source of the oscillator charging the capacitor of the oscillator for generating the oscillation signal in response to the control signal;
wherein the output signal is correlated to the oscillation signal, the current source of the oscillator is correlated to the current source of the period-to-voltage converter.

8. A method for frequency multiplying, comprising:
generating a control signal in response to the period of an input signal; and
generating an output signal in accordance with the control signal;
wherein the level of the control signal is corrected to the frequency of the input signal, the control signal is coupled to determine the frequency of the output signal.

9. The method as claimed in claim 8, wherein a time constant of generating the output signal is corrected to a time constant of generating the control signal.

10. The method as claimed in claim 9, wherein the time constant of generating the output signal and the time constant of generating the control signal determine a multiplier of the frequency multiplying.

11. The method as claimed in claim 8, wherein the output signal is synchronized with the input signal.

12. The method as claimed in claim 8, further comprising:
generating a differential signal in according with the control signal;
wherein the differential signal is coupled to generate the output signal.

13. The method as claimed in claim 12, further comprising:
receiving a bias signal for generating the differential signal in according with the control signal and the bias signal.

14. The method as claimed in claim 8, wherein the generating of the control signal comprising:
generating a ramp signal in response to the input signal; and
generating the control signal by sampling the ramp signal in response to the input signal;
wherein the level of the control signal is corrected to the period of the input signal.

15. The method as claimed in claim 8, wherein the generating of the output signal comprising:
generating an oscillation signal in response to the control signal; and
generating the output signal in response to the oscillation signal;
wherein the output signal is correlated to the oscillation signal.
